(19) United States
(12) Patent Application Publication
(10) Pub. No.: US 2009/0294162 A1
(43) Pub. Date: Dec. 3, 2009

(54) Printed circuit board and manufacturing method thereof

(75) Inventors: Kyoung-Jin Jeong, Suwon-si (KR); Jaewoo Joung, Suwon-si (KR); Kwansoo Yun, Suwon-si (KR); Rowoon Lee, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/318,917

(22) Filed: Jan. 12, 2009

(30) Foreign Application Priority Data
Jun. 2, 2008 (KR) 10-2008-0051817

(51) Int. Cl. H05K 1/18; B05D 5/12; B05D 3/04; B05D 3/00

(52) U.S. Cl. 174/260; 427/97.3; 427/535; 427/97.5

(57) ABSTRACT

Disclosed are a printed circuit board and a manufacturing method thereof. The printed circuit board, having an electronic component mounted thereon, in accordance with an embodiment of the present invention includes: a substrate having a circuit pattern and a pad formed on one side thereof; a solder resist layer formed on one side of the substrate so as to expose the pad; and a dam formed on the solder resist layer by an inkjet printing method and disposed at a position corresponding to where the electronic component is mounted so as to control a flow of an underfill solution injected between the substrate and the electronic component.

### CROSS-REFERENCE TO RELATED APPLICATIONS

This application claims the benefit of Korean Patent Application No. 10-2008-0051817, filed with the Korean Intellectual Property Office on Jun. 2, 2008, the disclosure of which is incorporated herein by reference in its entirety.

### BACKGROUND

1. Technical Field

The present invention relates to a printed circuit board and a manufacturing method thereof.

2. Description of the Related Art

Recently, with the development of the semiconductor technology, integration of a semiconductor package and demands for more functions, not only one chip but also multiple chips and semiconductor chips, such as a capacitor and a resister, are frequently mounted together on a substrate having a semiconductor chip mounted thereon. While use of flip chip packages (FCCSP) as a printed circuit board mounting semiconductor chips is rapidly increasing for the purpose of making electronic products smaller, there is a limit in reducing the size of a semiconductor package including the flip chip package (FCCSP) product, due to the flow control problem of an underfill solution used to mount a semiconductor chip.

For example, when mounting a chip on the flip chip package (FCCSP) product, it is difficult to effectively control the flow of the underfill solution injected between the printed circuit board and the semiconductor chip. The injected underfill solution penetrates through a pad, which is necessary for wire-bonding or solder ball junction. For that reason, the pad and the semiconductor may be contaminated.

### SUMMARY

The present invention provides a printed circuit board and a manufacturing method thereof that can prevent a pad from being contaminated and control the flow of an underfill solution when injecting the underfill solution by forming a dam by means of an inkjet method.

An aspect of the present invention features a method of manufacturing a printed circuit board having an electronic component mounted thereon. The method of manufacturing a printed circuit board in accordance with an embodiment of the present invention can include: providing a substrate having a circuit pattern and a pad formed on one side thereof; forming a solder resist layer on one side of the substrate so as to expose the pad; and forming a dam on the solder resist layer with an inkjet printing method so as to control a flow of an underfill solution injected between the substrate and the electronic component, the dam being disposed at a position corresponding to where the electronic component is mounted.

A cross-section of the dam can have a convexly curved shape in the upper part thereof.

The forming of the solder resist layer on one side of the substrate can use an inkjet printing method.

Prior to the forming of the dam, plasma-treating the surface of the solder resist layer can be further performed.

The forming of the dam can include printing polymer ink on the solder resist layer with an inkjet printing method; and hardening the polymer ink

The polymer ink can include an acrylate-based compound or wax.

After the forming of the solder resist layer on one side of the substrate, further included can be forming of a dam pillar by printing a conductive material on the pad with an the inkjet printing method, which connects the pad to the electronic component.

The forming of the dam and the forming of the dam pillar are performed in a same process. The dam pillar is taller than the dam.

Another aspect of the present invention features a printed circuit board having an electronic component mounted thereon. The printed circuit board in accordance with an embodiment of the present invention can include: a substrate, having a circuit pattern and a pad formed on one side thereof; a solder resist layer, formed on one side of the substrate so as to expose the pad; and a dam, formed on the solder resist layer by an inkjet printing method and disposed at a position corresponding to where the electronic component is mounted so as to control a flow of an underfill solution injected between the substrate and the electronic component.

A cross-section of the dam can have a convexly curved shape in the upper part.

The solder resist layer can be formed by the inkjet printing method.

The printed circuit board mentioned above can be formed by printing a conductive material on the pad with an inkjet printing method, and can further include a dam pillar connecting the pad to the electronic component.

The dam pillar can be taller than the dam.

### BRIEF DESCRIPTION OF THE DRAWINGS

FIG. 1 illustrates a flowchart of a method of manufacturing a printed circuit board according to an embodiment of the present invention.

FIGS. 2 to 5 illustrate a manufacturing process of a printed circuit board according to an embodiment, of the present invention.

FIGS. 6 to 10 illustrate cross sectional views showing a dam of a printed circuit board according to an embodiment of the present invention.

FIGS. 11 to 13 illustrate cross sectional views showing a surface treatment process of a solder resist layer in a method of manufacturing a printed circuit board according to an embodiment of the present invention.

FIG. 14 illustrates a perspective view of a printed circuit board according to an embodiment of the present invention.

FIG. 15 illustrates a cross sectional view of a printed circuit board according to an embodiment of the present invention.

FIG. 16 illustrates a cross sectional view of a printed circuit board according to another embodiment of the present invention.

FIG. 17 illustrates a cross sectional view of a printed circuit board according to yet another embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention. In the following description of the present invention, the detailed description of known technologies incorporated herein will be omitted when it may make the subject matter unclear.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, embodiments of a printed circuit board and a manufacturing method thereof will be described in detail with reference to the accompanying drawings. In description with reference to accompanying drawings, the same reference numerals will be assigned to the same or corresponding elements, and repetitive descriptions thereof will be omitted.

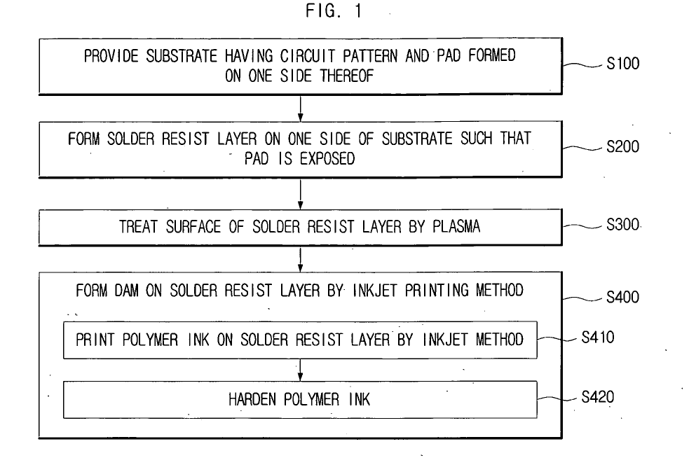

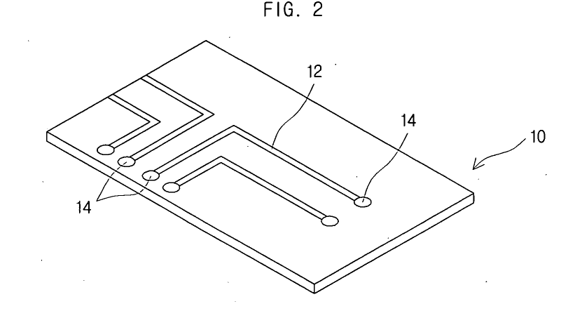

FIG. 1 illustrates a flowchart of a method of manufacturing a printed circuit board according to an embodiment of the present invention. FIGS. 2 to 5 illustrate a flow of a manufacturing process of a printed circuit board according to an embodiment of the present invention. Illustrated in FIGS. 2 to 5 are a substrate 10, a circuit pattern 12, a pad 14, a solder resist layer 20, a dam 30 and an inkjet head 40.

Provided according to an embodiment of the present invention is the substrate 10 having the circuit pattern 12 and the pad 14 formed on one side thereof (S100). The circuit pattern and the pad can be formed on an insulating substrate. The circuit pattern and the pad are designed according to transfer flow of an electronic signal required by the substrate 10. That is, the circuit pattern and the pad are made of a conductive material, playing the role of transferring an electronic signal and making an electrical connection.

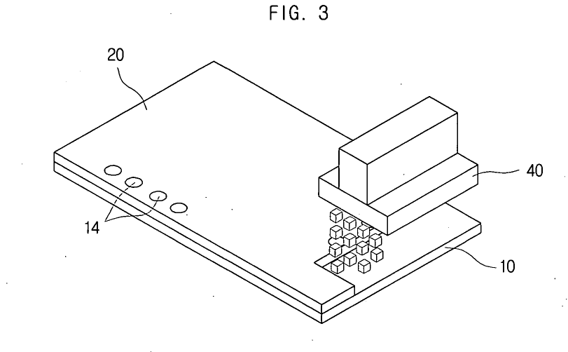

Then, the solder resist layer 20 is formed on one side of the substrate 10, as illustrated in FIG. 3 (S200). The solder resist layer prevents a short-circuit between the circuit patterns 12 when joining the solder ball 50 with the surface of the substrate or mounting an electronic component on the surface of the substrate. The solder resist layer, which is made of an insulating material, covers the circuit pattern, thereby ensuring electrical reliability of the circuit pattern 12.

The solder resist layer 20 is formed such that the pad 14 requiring electrical connection to the outside can be exposed to the outside. The pad 14 is joined with an electronic component by a solder ball 50 or is wire-bonded to an electronic component. Accordingly, an external electronic component can be electrically connected to the circuit pattern 12 inside the substrate 10 through the pad 14 exposed to the outside.

According to an embodiment of the present invention, as illustrated in FIG. 3, the solder resist layer can be formed by using the inkjet printing method, in which solder resist ink is sprayed on one side of the substrate 10. As illustrated in FIG. 3, the solder resist ink is jetted through the inkjet head 40. As the jetted solder resist ink is hardened, the solder resist layer 20 can be formed on one side of the substrate 10.

As in an embodiment of the present invention, the solder resist layer 20 can be precisely formed on a desired area of the substrate only, by forming the solder resist layer 20 through the inkjet printing method. According to this embodiment, the solder resist ink can be precisely jetted on the parts other than the pad 14, by using the inkjet head 40. Accordingly, it is possible to precisely expose the fine pad designed not to be covered by the solder resist layer 20.

While an embodiment of the present invention describes the process of forming the solder resist layer 20 through the inkjet printing method with reference to FIG. 3, it would be also possible that the solder resist ink is applied on the entire surface of the substrate 10 and then selectively exposed and developed, to open the pad 14 only. In other words, any method of forming the solder resist layer and opening the pad through a photolithography process shall be also included in the technical ideas and scope of the present invention.

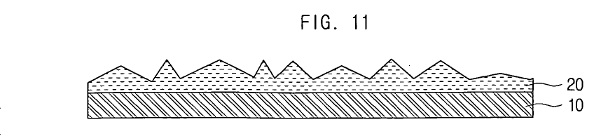

In forming a dam 30 after forming the solder resist layer 20, according to an embodiment of the present invention, the surface of the solder resist layer 20 can be treated by plasma before forming the dam (S300). Treating the surface can prevent a possible height difference in the dam. The surface treatment process of the solder resist layer will be described later with reference to FIGS. 11 to 13.

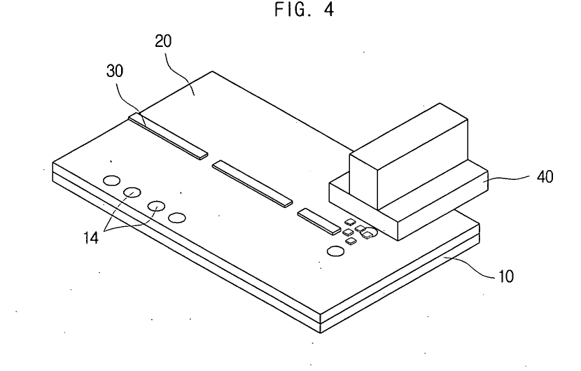

The dam 30 is formed on the solder resist layer 20, as illustrated in FIG. 4 (S400). The dam can be formed by the inkjet printing method. The dam having a certain pattern and shape is formed on the solder resist layer, thereby performing a function of controlling the flow of the underfill solution. For example, when injecting the underfill solution, the dam prevents the underfill solution from overflowing. The underfill solution is injected into a gap between the printed circuit board and an electronic component mounted on the printed circuit board. A gap for connecting the electronic component to the printed circuit board is filled by injecting and hardening the underfill solution.

That is, the dam 30 can be formed at a position corresponding to the position of the mounted electronic component, such that the underfill solution, which is injected to secure the connection between the electronic component and the substrate, is prevented from overflowing. When the dam is formed outside the electronic component, the dam performs a function of preventing the pad 14 exposed to the outside of the dam from being contaminated by the underfill solution during the process of injecting the underfill solution.

When the dam 30 is formed inside the electronic component, the dam can control how low the underfill solution is injected in the electronic component. That is, if the property of the electronic component or the substrate does not require that the underfill solution be injected into the entire surface of the lower side of the electronic component, the dam can be formed inside the electronic component.

The dam 30 is designed to be formed outside or inside the electronic component with the consideration of the mounting position of the electronic component and the injecting position of the underfill solution. The dams can be also designed to be formed both outside and inside the electronic component.

According to this embodiment of the present invention, the dam 30 is formed as follows, as illustrated in FIG. 4. First, polymer ink is printed on the solder resist layer by the inkjet method. The polymer ink is injected into the inkjet head 40 and is printed on the solder resist layer 20 through the inkjet head according to the desired pattern.

The polymer ink is jetted through the inkjet head 40 by a bubble jet method or piezoelectric jet method. In the piezoelectric jet method, the ink is jetted by using a piezoelectric substance, which vibrates with a supplied voltage. That is, the piezoelectric jet method uses a principle that a piezoelectric substance lengthened by the supplied voltage gives a pressure to the ink, thereby jetting the ink to the outside. In the bubble jet method, the ink is jetted by vaporizing the water inside the ink through instantaneous high temperature from a heating plate.

The polymer ink used for inkjet printing in order to form the dam 30 can include an acrylate-based compound or wax. Ink containing between 70 and 100 weight percent of the acrylate-based compound or wax can be used.

After the polymer ink is printed in the shape of the dam 30, the printed polymer ink is hardened. The polymer ink is hardened by being exposed to ultraviolet rays or heat. The polymer ink can be also hardened by being exposed to both heat and the ultraviolet rays.

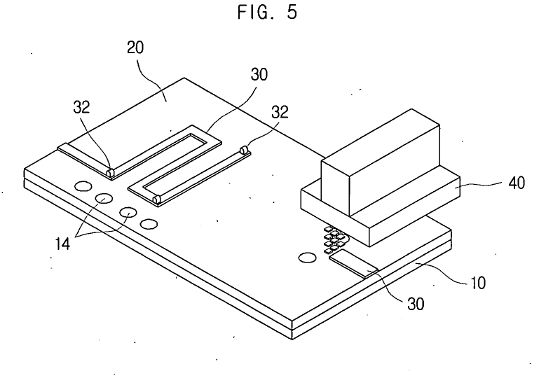

Through the method described above, the dam 30 having various patterns and heights can be made as illustrated in FIG. 5. By using the inkjet printing method, it is possible to adjust the pattern, height and width of the dam in accordance with design intent. In other words, it is possible to easily form a dam having a complex but detailed structure.

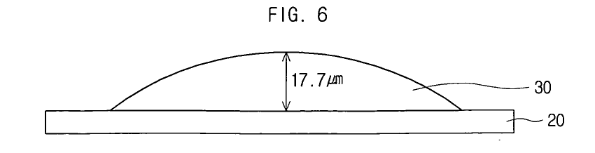

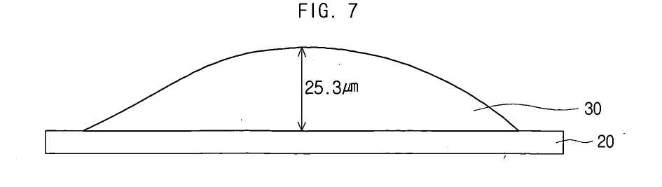

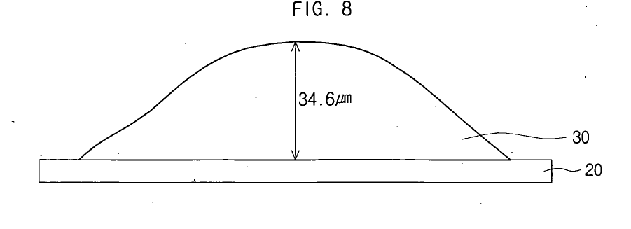

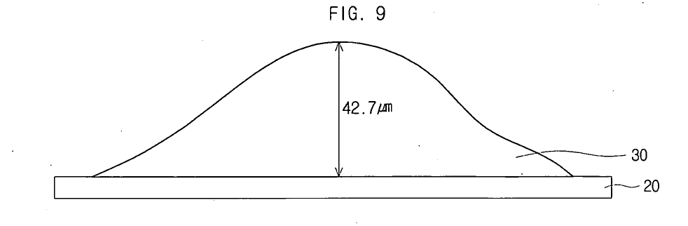

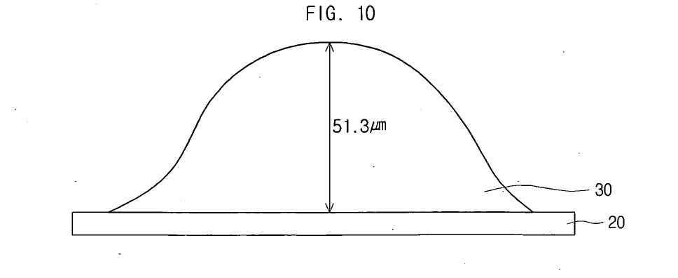

FIGS. 6 to 10 illustrate a cross sectional view showing a dam of a printed circuit board according to an embodiment of the present invention. Illustrated in FIGS. 6 to 10 is a section of a dam 30 having a height adjusted in a micro unit according to an embodiment of the present invention.

In a forming process of a dam 30 in accordance with an embodiment of the present invention, it is possible to adjust the ingredient and concentration of the polymer ink used in the inkjet printing method and the amount of the ink jetted from the inkjet head 40 in accordance with design intent.

After the dam 30 is formed, the height and width of the dam is changeable according to the height of the electronic component to be mounted and the property of the underfill solution. Therefore, there can be less restriction on how the dam is designed when manufacturing the printed circuit board.

Referring to FIGS. 6 to 10, the cross-section of the dam 30 has a convexly curved shape in the upper part. Owing to the viscosity of the ink jetted by the inkjet head 40, the dam has a convex arch-shape. The dam 30 can be made in the shape of a hemisphere or a bell in accordance with the composition and amount of the jetted polymer ink.

The dam 30 can be made of a material that is repulsive to the underfill solution. The material that is repulsive to the underfill solution is added to the polymer ink for forming the dam. The dam 30 formed in such a manner comes in contact with the underfill solution. Since the dam has a section having a convexly curved shape in the upper part, the area repulsed between the underfill solution and the dam can be increased.

Forming the dam 30 to be repulsive to the underfill solution and maximizing the repulsion area between the underfill solution and the dam can effectively prevent the underfill solution from overflowing.

According to an embodiment of the present invention, the surface 70 of the solder resist layer 20 having a dam formed thereon can be treated by plasma before forming the dam 30. The solder resist layer surface treatment process S300 will be described with reference to the following FIGS. 11 to 13.

The surface of the solder resist layer 20 formed on one side of the substrate 10 is made rough, as illustrated in FIG. 11. With a magnified view of the substrate, the roughness of the solder resist layer has different heights along the surface. The height of the dam 30 is affected by the height difference of roughness along the surface of the solder resist layer.

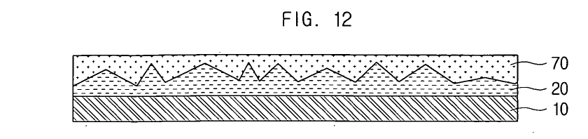

Therefore, a surface treatment process for reducing the roughness of the surface of the solder resist layer 20 is performed as illustrated in FIG. 12. According to this embodiment of the present invention, the surface treatment process can be performed by high temperature and high pressure plasma treatments on the solder resist layer 20. Such surface treatment processes can be also performed by processes that can cause physiochemical surface change by use of ultraviolet (UV) energy, heat energy or Nitrogen (N₂) gas.

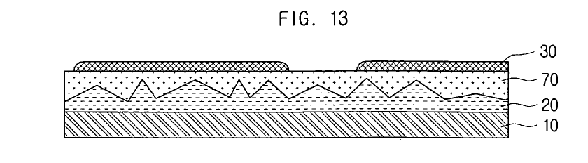

Subsequently, the height difference of the dam can be further prevented by forming the dam 30 on the surface-treated solder resist layer 20, as illustrated in FIG. 13. Formed to have a constant height, the dam can equally prevent the underfill solution from overflowing throughout the area of the solder resist layer. That is, according to this embodiment of the present invention, if the amount of jetted polymer ink is the same as that of the jetted inkjet head 40, it is possible to predetermine the precise height of the dam to be formed.

Meanwhile, further performed after the dam 30 is formed can be a process of restoring the surface of the solder resist layer 20 having changed physiochemical property through the surface treatment process mentioned above. The surface is restored physicochemically by use of ultraviolet (UV) energy, heat energy or nitrogen (N₂) gas in the manner similar to the surface treatment process mentioned above. These procedures can be used to restore the property of the solder resist layer 20 having no dam formed thereon, and to prevent the effect of the plasma treatment, which may occur when mounting the electronic component or injecting the underfill solution.

According to an embodiment of the present invention, after forming the solder resist layer on the substrate 10, a dam pillar 32 can be formed on the pad 14. The dam pillar 32 can be formed by the inkjet printing method, which is used to form the dam.

The process of forming the dam pillar 32 can be the same as that of forming the dam. In other words, both processes are performed by adjusting the amount of ink jetted by the inkjet head 40 through the same inkjet printing method. Accordingly, the dam pillar 32 can be formed on the exposed pad 14 having a taller shape than that of the dam 30 in the middle of or at the end of the dam 30. The dam pillar 32 can be also independently formed and separated from the dam 30.

The dam pillar 32 is formed taller than the dam 30 such that it connects the electronic component to the pad. According to this embodiment of the present invention, the dam pillar is made of a conductive material, which is connected to the electronic component and formed on the pad 14. That is, the dam pillar 32 can be formed by printing the conductive material on the pad with the inkjet printing method. Therefore, the dam pillar 32 is capable of electrically connecting the electronic component to the substrate 10.

When forming the dam, a greater amount of conductive ink is jetted on the exposed pad 14. The dam pillar can be formed by hardening the conductive ink. The dam pillar supports the electronic component and connects the electronic component to the substrate 10.

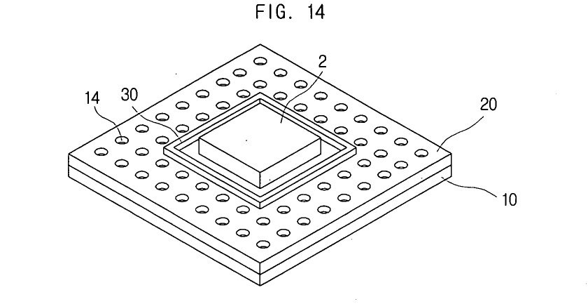

Hereinafter, a printed circuit board according to an embodiment of the present invention will be described with reference to FIGS. 14 to 17.

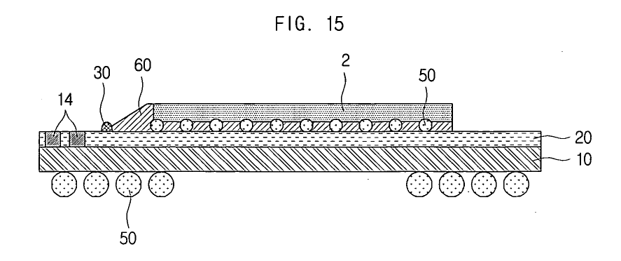

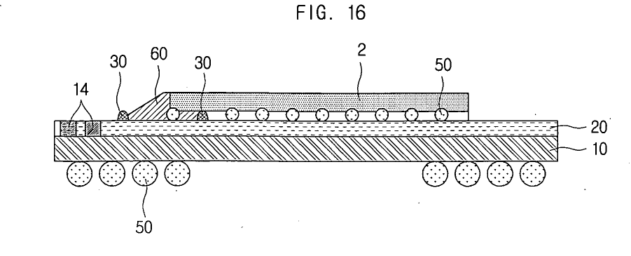

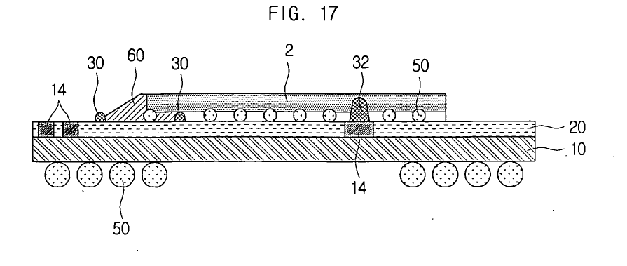

FIG. 14 illustrates a perspective view of a printed circuit board according to an embodiment of the present invention. FIG. 15 illustrates a cross sectional view of a printed circuit board according to an embodiment of the present invention. FIG. 16 illustrates a cross sectional view of a printed circuit board according to another embodiment of the present invention. FIG. 17 illustrates a cross sectional view of a printed circuit board according to yet another embodiment of the present invention.

As illustrated in FIGS. 14 and 15, the dam 30 formed by the inkjet printing method is formed outside the electronic component 2 so that the pad 14 outside the electronic component 2 is prevented from being contaminated. As illustrated in FIG. 15, the underfill solution 60 is interrupted and flowed to the inside of the electronic component 2. Accordingly, the gap between the electronic component and the substrate 10 is filled with the underfill solution.

According to another embodiment of the present invention, as illustrated in FIG. 16, the dams 30 are formed outside and inside the electronic component 2 so that the underfill solution 60 can be controlled to be injected into only a part of the gap between the substrate 10 and the electronic component 2. The dams 30 outside and inside the electronic component 2 also prevent the pad 14 under the electronic component 2 from being contaminated. That is, it is possible to inject the underfill solution 60 into only a minimum gap for strengthening the connection between the substrate 10 and the electronic component 2.

As illustrated in FIG. 17, the dam pillar 32 can be formed on the pad 14 with the inkjet printing method. The dam pillar 32 is made of a conductive material and comes in contact with the electronic component 2. The electronic component is electrically connected to the substrate 10 through the dam pillar 32, which is formed on the pad 14 and connected to the electronic component 2. The dam pillar 32 can be also formed to support the electronic component 2.

In the illustrations of FIGS. 15 to 17, as described above, the cross-section of the dam 30 has a convexly curved shape in the upper part, and the underfill solution 60 can be effectively prevented from overflowing by using the repulsive property of the dam and the underfill solution 60.

While certain embodiments of the present invention have been described, it shall be understood by those skilled in the art that various modifications and permutations of the present invention are possible without departing from the spirit and scope of the present invention as defined by the appended claims.

Numerous embodiments other than the embodiments described above are included within the scope of the present invention.

What is claimed is:

1. A method of manufacturing a printed circuit board having an electronic component mounted thereon, the method comprising:
providing a substrate having a circuit pattern and a pad formed on one side thereof;
forming a solder resist layer on one side of the substrate so as to expose the pad; and
forming a dam on the solder resist layer with an inkjet printing method so as to control a flow of an underfill solution injected between the substrate and the electronic component, the dam being disposed at a position corresponding to where the electronic component is mounted.

2. The method of claim 1, wherein a cross-section of the dam has a convexly curved shape in the upper part.

3. The method of claim 1, wherein the forming of the solder resist layer on one side of the substrate uses an inkjet printing method.

4. The method of claim 1, further comprising, prior to the forming of the dam, plasma-treating the surface of the solder resist layer.

5. The method of claim 1, wherein the forming of the dam comprises:
printing polymer ink on the solder resist layer with an inkjet printing method; and
hardening the polymer ink.

6. The method of claim 5, wherein the polymer ink comprises an acrylate-based compound or wax.

7. The method of claim 1, further comprising, after the forming of the solder resist layer on one side of the substrate, forming a dam pillar by printing a conductive material on the pad with an inkjet printing method, the dam connecting the pad to the electronic component.

8. The method of claim 7, wherein the forming of the dam and the forming of the dam pillar are performed in a same process.

9. The method of claim 7, wherein the dam pillar is taller than the dam.

10. A printed circuit board having an electronic component mounted thereon, the printed circuit board comprising:
a substrate, having a circuit pattern and a pad formed on one side thereof;
a solder resist layer, formed on one side of the substrate so as to expose the pad; and
a dam, formed on the solder resist layer by an inkjet printing method and disposed at a position corresponding to where the electronic component is mounted so as to control a flow of an underfill solution injected between the substrate and the electronic component.

11. The printed circuit board of claim 10, wherein a cross-section of the dam has a convexly curved shape in the upper part.

12. The printed circuit board of claim 10, further comprising a dam pillar formed by printing a conductive material on the pad with an inkjet printing method, the dam pillar connecting the pad to the electronic component.

13. The printed circuit board of claim 12, wherein the dam pillar is taller than the dam.
